(19) United States
(12) Patent Application Publication
(10) Pub. No.: US 2011/0284162 A1
(43) Pub. Date: Nov. 24, 2011

(54) APPARATUS FOR WET PROCESSING SUBSTRATE

(75) Inventors: ZONG-QING CAI, Shenzhen City (CN); TUNG-YAO KUO, Tayuan (TW)

(73) Assignees: FOXCONN ADVANCED TECHNOLOGY INC., Tayuan (TW); FUKUI PRECISION COMPONENT (SHENZHEN) CO., LTD., Shenzhen City (CN)

(21) Appl. No.: 12/913,789

(22) Filed: Oct. 28, 2010

(30) Foreign Application Priority Data
May 20, 2010 (CN) 201010178139.7

(51) Int. Cl. H01L 21/306

(52) U.S. Cl. 156/345.16; 156/345.17; 156/345.21

(57) ABSTRACT

An exemplary apparatus for wet processing a substrate includes a conveyor configured for conveying the substrate along a conveying direction and parallel spray pipes. The spray pipes are substantially parallel with the conveyor and substantially perpendicular to the conveying direction. Each spray pipe consisting of at least one spray nozzle faces the conveyor, and the number of the at least one nozzle of each spray pipe increases along the conveying direction.

### BACKGROUND

1. Technical Field

The present disclosure relates to an apparatus for processing a substrate, and particularly, to an apparatus for wet processing a printed circuit board (PCB).

2. Description of Related Art

In the manufacture of PCBs, it is normal practice to feed the boards through a series of processing machines via a conveyor system. The process includes resist stripping, pre-cleaning, etching, neutralizing, water rinsing, and drying. Pre-cleaning, etching, neutralizing, and water rinsing, are known as wet processing steps. In these wet processing steps, a spray system comprising of at least one set of spray nozzles is arranged to face the conveyor system to spray wet processing liquid on PCBs on the conveyor system. For example, the spray system can spray etchant on the PCBs to form circuits therein.

However, a puddle of etchant is inevitably formed in a central portion of the PCB due to the fact that flow velocity of etchant in a peripheral portion of the PCB is faster than in the central portion of the PCB. This “puddle effect” leads to different etching rates in the central and peripheral portions of the PCB. In such case the accuracy of the circuits and the electrical properties of the PCBs are affected.

What is needed, therefore, is an apparatus for wet processing a substrate, and a method for wet processing the substrate using the apparatus, which can overcome the above-described problem.

### BRIEF DESCRIPTION OF THE DRAWINGS

FIG. 1 is a schematic view of an apparatus for wet processing a substrate according to a first embodiment.

FIG. 2 is a schematic view of the apparatus with a substrate of FIG. 1.

FIG. 3 is a schematic view illustrating spray areas formed by spray pipes of the apparatus spraying wet processing liquid on the substrate.

FIG. 4 is a schematic view of an apparatus for wet processing a substrate according to a second embodiment.

### DETAILED DESCRIPTION

Embodiments will now be described in detail below with reference to drawings.

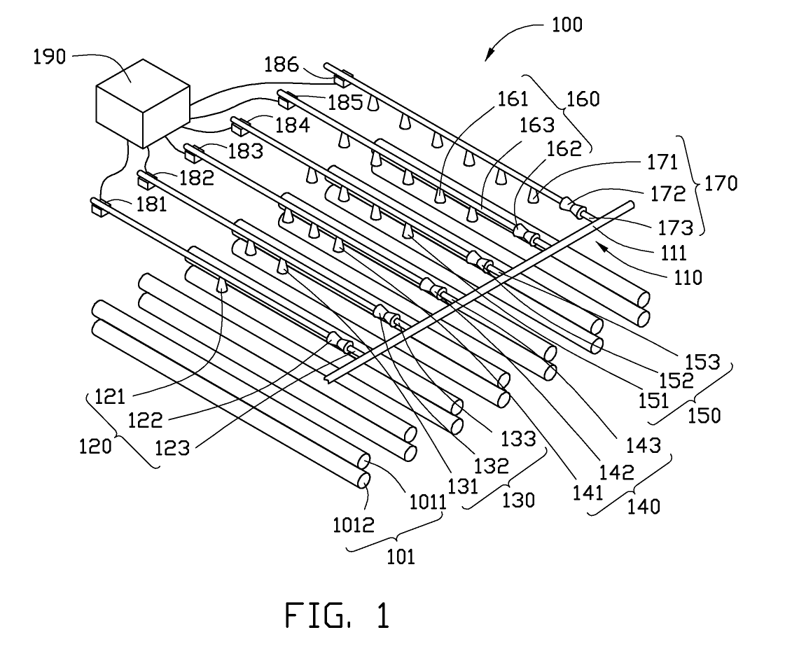

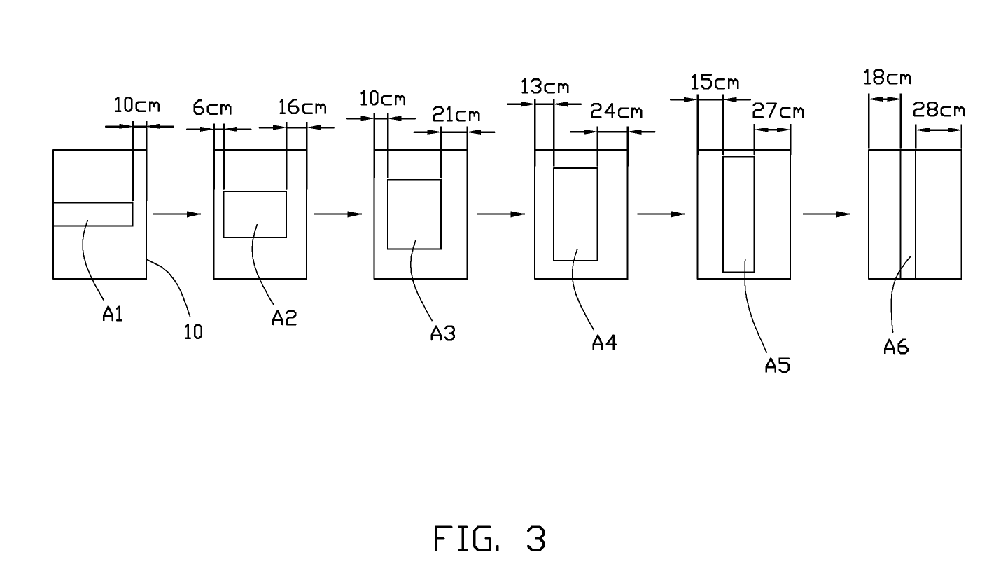

Referring to FIG. 1, an apparatus 100 for wet processing a substrate 10 (referring to FIG. 3) using a wet processing liquid (not shown), in accordance with a first embodiment, is shown. The wet processing apparatus 100 includes an infusion device 110, a first spray pipe 120, a second spray pipe 130, a third spray pipe 140, a fourth spray pipe 150, a fifth spray pipe 160, a sixth spray pipe 170, a first sensor 181, a second sensor 182, a third sensor 183, a fourth sensor 184, a fifth sensor 185, a sixth sensor 186, a controlling device 190, and a conveyor 101 for conveying the substrate along a conveying direction.

In the present embodiment, the infusion device 110 includes an infusion pipe 111 communicating with the pipes 120-170. The infusion pipe 111 is configured for supplying wet processing liquid, such as an etchant, to the pipe 120, the pipe 130, the pipe 140, the pipe 150, the pipe 160, and the pipe 170. In other embodiments, a valve (not shown) may be installed on the infusion pipe 111 for controlling whether the wet processing liquid enters into the infusion pipe 111 or not, and adjusting a flow velocity of the wet processing liquid in the infusion pipe 111.

The pipe 120, the pipe 130, the pipe 140, the pipe 150, the pipe 160, and the pipe 170 are substantially parallel with each other as well as the conveyor 101, and substantially perpendicular to the conveying direction. The pipe 120, the pipe 130, the pipe 140, the pipe 150, the pipe 160, and the pipe 170 communicate with the infusion pipe 111. In the present embodiment, the pipe 120, the pipe 130, the pipe 140, the pipe 150, the pipe 160, and the pipe 170 are equidistantly spaced, and have the same length. The length of the pipe 120 is equal to or slightly longer than that of the substrate 10 to be wet processed. When the substrate 10 is in the wet process, the lengthwise direction of the infusion pipe 111 is identical to the moving direction of the substrate 10. In the present embodiment, the substrate 10 is conveyed along a conveying direction from the pipe 120 to the pipe 170. In alternative embodiments, the number of the spray pipes is not limited to six.

In the present embodiment, the pipe 120 includes a first spray nozzle 121 facing the conveyor 101, a first valve 122, and a first pipe body 123. The nozzle 121 is located at the middle of the body 123. The valve 122 is arranged on the body 123, and is located between the nozzle 121 and the infusion pipe 111. The valve 122 is configured for controlling whether the wet processing liquid in the infusion pipe 111 is supplied to the nozzle 121 or not, thereby controlling whether the nozzle 121 sprays the wet processing liquid on the substrate 10 or not.

The pipe 130 includes two second spray nozzles 131 facing the conveyor 101, a second valve 132, and a second pipe body 133. The two nozzles 131 are located at the middle of the body 133. The two nozzles 131 are axially symmetrical about a central axis of the body 133. The valve 132 is arranged on the body 133, and is located between one nozzle 131, which is nearer to the infusion pipe 111 than the other nozzle 131, and the infusion pipe 111. The valve 132 is configured for controlling whether the wet processing liquid in the infusion pipe 111 is supplied to the nozzles 131 or not, thereby controlling whether the nozzles 131 spray wet processing liquid on the substrate 10 or not.

The pipe 140 includes three spray nozzles 141 facing to the conveyor 101, a third valve 142, and a third pipe body 143. The three nozzles 141 are located at the middle of the body 143. The three nozzles 141 are equidistantly spaced along a direction perpendicular to the conveying direction. In the present embodiment, the distance between each two adjacent nozzles 141 is equal to the distance between the two nozzles 131. The valve 142 is arranged on the body 143, and is located between one nozzle 141, which is nearer to the infusion pipe 111 than other nozzles 141, and the infusion pipe 111. The valve 142 is configured for controlling whether the wet processing liquid in the infusion pipe 111 is supplied to the nozzles 141 or not, thereby controlling whether the nozzles 141 spray wet processing liquid on the substrate 10 or not.

The pipe 150 includes four fourth spray nozzles 151 facing to the conveyor 101, a fourth valve 152, and a fourth pipe body 153. The four nozzles 151 are located at the middle of the body 153, and are equidistantly spaced along a direction perpendicular to the conveying direction. In the present embodiment, the distance between each two adjacent nozzles 151 is equal to the distance between the two nozzles 131. The valve 152 is arranged on the body 153, and is located between one nozzle 151, which is nearer to the infusion pipe 111 than other nozzles 151, and the infusion pipe 111. The valve 152 is configured for controlling whether the wet processing liquid in the infusion pipe 111 is supplied to the nozzles 151, thereby controlling whether the nozzles 151 spray wet processing liquid on the substrate 10 or not.

The pipe 160 includes five fifth spray nozzles 161 facing to the conveyor 101, a fifth valve 162, and a fifth pipe body 163. The five nozzles 161 are located at the middle of the body 163, and are equidistantly spaced along a direction perpendicular to the conveying direction. In the present embodiment, the distance between each two adjacent nozzles 161 is equal to the distance between the two nozzles 131. The valve 162 is arranged on the body 163, and is located between one nozzle 161, which is nearer to the infusion pipe 111 than other nozzles 161, and the infusion pipe 111. The valve 162 is configured for controlling whether the wet processing liquid in the infusion pipe 111 is supplied to the nozzles 161, thereby controlling whether the nozzles 161 spray wet processing liquid on the substrate 10 or not.

The pipe 170 includes six sixth spray nozzles 171 facing to the conveyor 101, a sixth valve 172, and a sixth pipe body 173. The six nozzles 171 are located at the middle of the body 173, and are equidistantly spaced along a direction perpendicular to the conveying direction. In the present embodiment, the distance between each two adjacent nozzles 171 is equal to the distance between the two nozzles 131. The valve 172 is arranged on the body 173, and is located between one nozzle 171, which is nearer to the infusion pipe 111 than other nozzles 171, and the infusion pipe 111. The valve 172 is configured for controlling whether the wet processing liquid in the infusion pipe 111 is supplied to the nozzles 171, thereby controlling whether the nozzles 171 spray wet processing liquid on the substrate 10 or not.

In the present embodiment, the valve 122, the valve 132, the valve 142, the valve 152, the valve 162, and the valve 172 are pneumatic valves, and are electrically connected with the controlling device 190. The nozzle 121, the nozzles 131, the nozzles 141, the nozzles 151, the nozzles 161, and the nozzles 171 are located towards the substrate 10 to be wet processed. The nozzle 121, the nozzles 131, the nozzles 141, the nozzles 151, the nozzles 161, and the nozzles 171 are arranged in a substantially isosceles triangular array along the conveying direction. In alternative embodiments, the numbers of the nozzle 121, the nozzles 131, the nozzles 141, the nozzles 151, the nozzles 161, the nozzles 171 are not limited to one, two, three, four, five, and six, respectively. In further alternative embodiments, the nozzle 121, the nozzles 131, the nozzles 141, the nozzles 151, the nozzles 161, and the nozzles 171 may be arranged a substantially inverted isosceles triangular array, a substantially isosceles trapezoidal array along the conveying direction, etc. In still further alternative embodiments, the nozzle 121, the nozzles 131, the nozzles 141, the nozzles 151, the nozzles 161, the nozzles 171 are not limited to be located at the middles of the corresponding pipe bodies, respectively.

The sensor 181, the sensor 182, the sensor 183, the sensor 184, the sensor 185, and the sensor 186 spatially correspond to the pipe 120, the pipe 130, the pipe 140, the pipe 150, the pipe 160, and the pipe 170, respectively. The sensor 181 is configured for sensing a position of the substrate 10 relative to the pipe 120, and transmitting the sensed value to the controlling device 190. The sensor 182 is configured for sensing a position of the substrate 10 relative to the pipe 130, and transmitting the sensed value to the controlling device 190. The sensor 183 is configured for sensing a position of r the substrate 10 relative to the pipe 140, and transmitting the sensed value to the controlling device 190. The sensor 184 is configured for sensing a position of the substrate 10 relative to the pipe 150, and transmitting the sensed value to the controlling device 190. The sensor 185 is configured for sensing a position of the substrate 10 relative to the pipe 160, and transmitting the sensed value to the controlling device 190. The sensor 186 is configured for sensing a position of the substrate 10 relative to the pipe 170, and transmitting the sensed value to the controlling device 190.

In the present embodiment, the sensors 181-186 are respectively arranged on the pipe 120, the pipe 130, the pipe 140, the pipe 150, and the pipe 160.

The controlling device 190 is electrically connected with the sensors 181-186, and the valves 122-172. The controlling device 190 is configured for controlling the corresponding valves to open or close based on the sensed values sensed by the corresponding sensors, thereby controlling whether the corresponding spray nozzles spray wet processing liquid on the substrate 10 or not. In detail, according to the sensed value sensed by the sensor 181, the controlling device 190 controls the valve 122 to open or close. According to the sensed value sensed by the sensor 182, the controlling device 190 controls the valve 132 to open or close. According to the sensed value sensed by the sensor 183, the controlling device 190 controls the valve 142 to open or close. According to the sensed value sensed by the sensor 184, the controlling device 190 controls the valve 152 to open or close. According to the sensed value sensed by the sensor 185, the controlling device 190 controls the valve 162 to open or close. According to the sensed value sensed by the sensor 186, the controlling device 190 controls the valve 172 to open or close.

The top of the conveyor 101 is oriented towards the nozzles 121-171, and the conveyor 101 is configured for conveying the substrate 10 to be wet processed at a uniform speed along the conveying direction, thereby making the substrate 10 pass underneath the pipe 120, the pipe 130, the pipe 140, the pipe 150, the pipe 160, and the pipe 170 in that order. In the present embodiment, the conveyor 101 includes a plurality of separated pairs of rollers (see below), which are below the pipe 120, the pipe 130, the pipe 140, the pipe 150, the pipe 160, and the pipe 170. The pairs of the rollers are equidistantly arranged along the conveying direction along which the substrate 10 is conveyed, and are parallel with each other. Each pair of rollers includes an upper roller 1011, and a lower roller 1012 opposite to the upper roller 1011. The distance between the upper roller 1011 and the lower roller 1012 is slightly smaller than the thickness of the substrate 10. The upper rollers 1011 are parallel with the pipe 120, the pipe 130, the pipe 140, the pipe 150, the pipe 160, and the pipe 170. The lower rollers 1012 are parallel with the upper rollers 1011. It is noted that a direction of rotation of the upper roller 1011 is reverse to that of the lower roller 1012. Thus, if the substrate 10 is placed between the upper rollers 1011 and the lower rollers 1012, the substrate 10 can be moved along a lengthwise direction of the infusion pipe 111 by the rotating of the upper and lower rollers 1011, 1012.

In the present embodiment, because the number of the spray nozzles along the moving direction of the substrate 10 is increased gradually, and each spray pipe has a valve, whether the corresponding spray nozzles spray wet processing liquid on the substrate 10 is easily controlled in the wet process, thereby easily controlling the spray areas of the corresponding spray pipes on the substrate 10. Accordingly, the uniformity of the wet process can be improved.

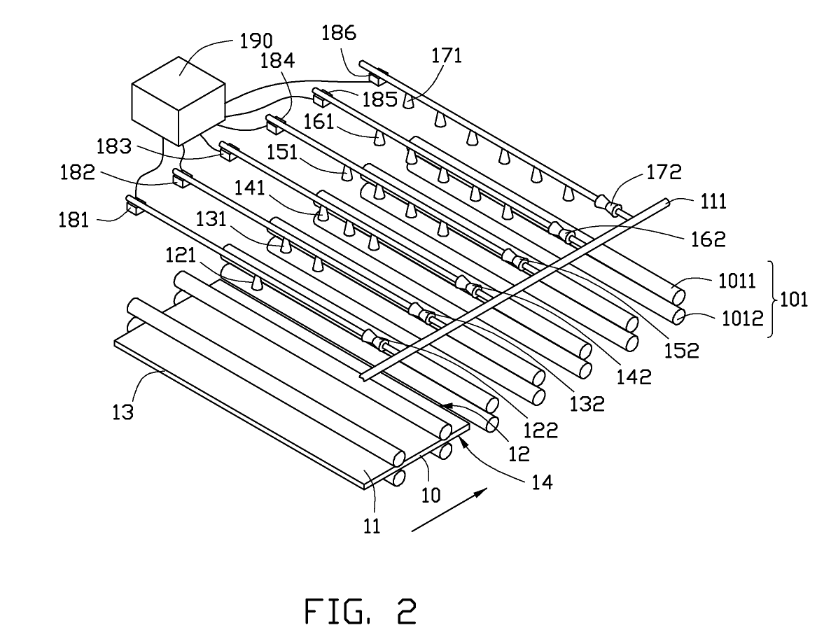

Referring to FIG. 2, a usage method of the apparatus 100 will be described below.

The wet processing apparatus 100 is firstly provided.

A substrate 10 to be wet processed is provided. The substrate 10 is a substantially rectangle substrate, and the length of the substrate 10 is substantially equal to the length of the pipe 120. In the present embodiment, the length of the substrate 10 is about 61 centimeters, and the width of the substrate 10 is about 53 centimeters. The substrate 10 includes a first surface 11 with copper formed thereon. The substrate 10 includes a front edge 12, and a rear edge 13.

Then, the substrate 10 is located at the left side of the conveyor 101, which is near to the pipe 120. The first surface 11 is oriented in a direction towards the pipe 120, and contacts with the upper rollers 1011. The bottom surface 14 opposite to the first surface 11 of the substrate 10 contacts with the lower rollers 1012 of conveyor 101. The front edge 12 and the rear edge 13 are perpendicular to the conveying direction and the center of the pipe 120 at the lengthwise direction of the pipe 120 is spatially corresponding to the center of the substrate 10 at the lengthwise direction of the substrate 10. The front edge 12 is near to the pipe 120, and the rear edge 13 is far away from the pipe 120. Then, the substrate 10 is conveyed to pass underneath the pipe 120, the pipe 130, the pipe 140, the pipe 150, the pipe 160, and the pipe 170 in that order, thereby making the substrate 10 wet processed by the wet processing liquid.

In the present embodiment, the controlling device 190 is configured for storing a plurality of first predetermined values each associated with a distance between the front edge 12 and a projection of a corresponding spray pipe on the substrate 10, and a plurality of second predetermined values each associated with a distance between the rear edge 13 and a projection of the corresponding spray pipe on the substrate 10. The controlling device 190 is configured for controlling the valve of the corresponding spray pipe to open if the sensed value is equal to the first predetermined value, and controlling the valve of the corresponding spray pipe to close if the sensed value is equal to the second predetermined value.

In the present embodiment, each of the first predetermined values is equal to a distance between the front edge 12 and a projection of a corresponding spray pipe on the substrate 10, and each of the second predetermined values is equal to a distance between the rear edge 13 and a projection of the corresponding spray pipe on the substrate 10.

The first predetermined values corresponding to the spray pipes gradually increase along the conveying direction. In other words, the first predetermined value between the front edge 12 and a projection of the spray pipe 120 is smaller than the first predetermined value between the front edge 12 and a projection of the spray pipe 130, and the first predetermined value between the front edge 12 and a projection of the spray pipe 130 is smaller than the first predetermined value between the front edge 12 and a projection of the spray pipe 140, etc.

The second predetermined values corresponding to the spray pipes gradually increase along the conveying direction. In other words, the second predetermined value between the rear edge 12 and a projection of the spray pipe 120 is smaller than the second predetermined value between the rear edge 13 and a projection of the spray pipe 130, and the second predetermined value between the rear edge 13 and a projection of the spray pipe 130 is smaller than the second predetermined value between the rear edge 13 and a projection of the spray pipe 140, etc.

The sensor 181, the sensor 182, the sensor 183, the sensor 184, the sensor 185, and the sensor 186 are respectively configured for sensing the distance values between the front edge 12 and the projections of the corresponding pipes 120-170 on the substrate 10 after the front edge 12 passes underneath the corresponding spray pipes 120-170, and the distance values between the rear edge 13 and the projections of the corresponding spray pipes 120-170 on the substrate 10 before the rear edge 13 passes underneath the corresponding spray pipes 120-170, and transmitting the sensed values to the controlling device 190.

The controlling device 190 controls the corresponding valves 122-172 to open or close, thereby controlling spray areas which the corresponding pipes 120-170 spray on the first surface 11. In detail, after the front edge 12 passes underneath the corresponding spray pipe, and if the sensed value between the front edge 12 and the projections of the corresponding spray pipe on the substrate 10 is equal to the corresponding first predetermined values between the front edge 12 and the projection of the corresponding spray pipe, the controlling device 190 controls the corresponding valve on the corresponding spray pipe to open. For example, after the front edge 12 passes underneath the pipe 120, and if the sensed value between the front edge 12 and the projection of the pipe 120 on the substrate 10 is equal to the first predetermined value between the front edge 12 and the projection of pipe 120 on the substrate 10, the controlling device 190 controls the valve 122 to open. Before the rear edge 13 passes underneath the corresponding pipes 120-170, and if the sensed value between the rear edge 13 and the corresponding spray pipes is equal to the corresponding second predetermined values between the rear edge 13 and the projection of the corresponding spray pipe on the substrate 10, the controlling device 190 controls the corresponding valve on the corresponding spray pipe to close. For example, before the rear edge 13 passes underneath the pipe 120, and if the sensed distance between the rear edge 13 and the projection of the pipe 120 on the substrate 10 is equal to the second predetermined value between the rear edge 13 and the projection of the pipe 120 on the substrate 10, the controlling device 190 controls the valve 122 to close.

In the present embodiment, the first predetermined values between the front edge 12 and the corresponding projections of the corresponding pipes 120-170 on the substrate 10 are +10 centimeters, +16 centimeters, +21 centimeters, +24 centimeters, +27 centimeters, and +28 centimeters, respectively; the second predetermined values between the rear edge 13 and the corresponding projections of the pipes 120-170 on the substrate 10 are −0 centimeters, −6 centimeters, −10 centimeters, −13 centimeters, −15 centimeters, and −18 centimeters, respectively. The sign “+” means the corresponding g first predetermined are the predetermined distances between the front edge 12 and the projections of the corresponding pipes 120-170 on the substrate 10 after the front edge 12 lastly passes underneath the corresponding pipes 120-170. The sign “−” means the corresponding second predetermined values are the predetermined distances between the rear edge 13 and the corresponding projections of the corresponding pipes 120-170 on the substrate 10 before the rear edge 13 lastly passes underneath the corresponding pipes 120-170.

In detail, take the pipe 120 for example, after the front edge 12 passes underneath the pipe 120, and the sensed distance between the front edge 12 and the projection of the pipe 120 on the substrate is 10 centimeters, the controlling device 190 controls the valve 122 to open, thereby making the nozzle 121 of the pipe 120 spray the wet processing solution on the surface 11. The substrate 10 moves continuously. Before the rear edge 13 passes underneath the pipe 120, and the sensed distance between the rear edge 13 and the projection of the pipe 120 on the substrate 10 is 0 centimeters, the controlling device 190 controls the valve 122 to close, thereby making the nozzle 121 of the pipe 120 stop spraying the wet processing solution on the surface 11.

Referring also to FIG. 3, area A1, area A2, area A3, area A4, area A5, and area A6 are respectively defined as the spray areas on the surface 11 of the substrate 10, and the arrow direction means the moving direction of the substrate 10. From the area A1 to area A6, the lengths of the area A1, area A2, area A3, area A4, area A5, and area A6 along the line arrow direction decrease gradually, and the lengths of the area A1, area A2, area A3, area A4, area A5, and area A6 along the direction perpendicular to the line arrow direction increase gradually (i.e., the time of the central area of the surface 11 being sprayed is longer than that of the peripheral area of the surface 11). In detail, the length of the area A1 along the line arrow direction is larger than that of area A2, and the length of the area A2 along the line arrow direction is larger than that of area A3, etc. The length of the area A1 along the direction perpendicular to the line arrow direction is smaller than that of the area A2, and the length of the area A2 along the direction perpendicular to the line arrow direction is smaller than that of the area A3, etc.

In the present usage method of the wet processing apparatus 100, because the number of the spray nozzles along the moving direction of the substrate 10 increases gradually, the time of the central area of the surface 11 being sprayed is longer than that of the peripheral area of the surface 11, thereby making the central area of the surface 11 in contact with more wet processing liquid than that in the conventional wet processing method. Therefore, a “puddle effect” on the substrate 10 can be avoided. In addition, the peripheral area of the surface 11 contacts with less wet processing liquid than that in the conventional wet processing method, over wet processing (e.g. over etching) at the peripheral area of the surface 11 can be avoided. Accordingly, the uniformity of wet processing can be improved.

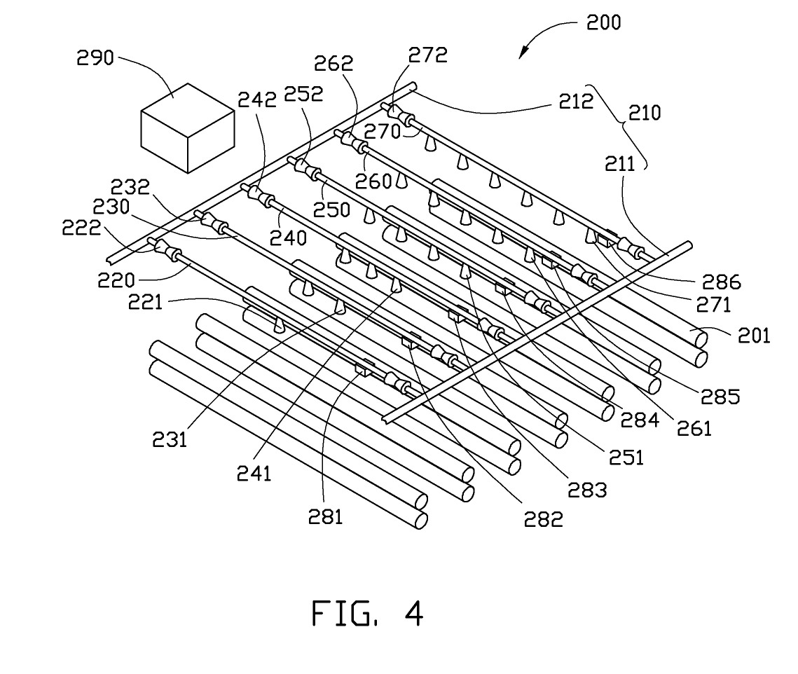

Referring to FIG. 4, an apparatus 200 for wet processing a substrate 10 using wet processing liquid, in accordance with a second embodiment, is shown. The structure of the apparatus 200 is similar with that of the apparatus 100. The apparatus 200 also includes an infusion device 210, a first spray pipe 220, a second spray pipe 230, a third spray pipe 240, a fourth spray pipe 250, a fifth spray pipe 260, a sixth spray pipe 270, a first sensor 281, a second sensor 282, a third sensor 283, a fourth sensor 284, a fifth sensor 285, a sixth sensor 286, a controlling device 290, and a conveyor 201. The structures, arrangements, and functions of the sensor 281, the sensor 282, the sensor 283, the sensor 284, the sensor 285, the sensor 286, the controlling device 290, and the conveyor 201 are similar to that of the sensor 181, the sensor 182, the sensor 183, the sensor 184, the sensor 185, the sensor 186, the controlling device 190, and the conveyor 101.

In the present embodiment, the infusion device 210 includes a first infusion pipe 211, and a second infusion pipe 212 parallel with the first infusion pipe 212. The lengthwise direction of the infusion pipe 211 is parallel with a conveying direction in which the substrate 10 is conveyed. The distance between the first infusion pipe 211 and the second infusion pipe 212 is slightly longer than the length of the substrate 10. The infusion pipe 211 and the second infusion pipe 212 are configured for supplying wet processing liquid to the pipe 220, the pipe 230, the pipe 240, the pipe 250, the pipe 260, and the pipe 270.

The arrangements of the pipe 220, the pipe 230, the pipe 240, the pipe 250, the pipe 260, the pipe 270 are similar to that of the pipe 120, the pipe 130, the pipe 140, the pipe 150, the pipe 160, and the pipe 170, except that, the pipe 220, the pipe 230, the pipe 240, the pipe 250, the pipe 260, and the pipe 270 are located between the first infusion pipe 211 and the second infusion pipe 212, and communicates with the first infusion pipe 211 and the second infusion pipe 212. In detail, one ends of the pipe 220, the pipe 230, the pipe 240, the pipe 250, the pipe 260, and the pipe 270 communicate with the first infusion pipe 211, and the other ends of the pipe 220, the pipe 230, the pipe 240, the pipe 250, the pipe 260, and the pipe 270 communicate with the second infusion pipe 212.

The arrangements of one first spray nozzle 221, two second spray nozzles 231, three third spray nozzles 241, four fourth spray nozzles 251, five fifth spray nozzles 261, and six sixth spray nozzles 271 are similar to that of the nozzle 121, the nozzles 131, the nozzles 141, the nozzles 151, the nozzles 161, and the nozzles 171.

Two first valves 222 are arranged on the two ends of the pipe 220, and are configured for whether the wet processing liquid in the first infusion pipe 211 and the second infusion pipe 212 is supplied to the pipe 220, respectively. Two second valves 232 are arranged on the two ends of the pipe 230, and are configured for whether the wet processing liquid in the first infusion pipe 211 and the second infusion pipe 212 is supplied to the pipe 230, respectively. Two third valves 242 are arranged on the two ends of the pipe 240, and are configured for whether the wet processing liquid in the first infusion pipe 211 and the second infusion pipe 212 is supplied to the pipe 240, respectively. Two fourth valves 252 are arranged on the two ends of the pipe 250, and are configured for whether the wet processing liquid in the first infusion pipe 211 and the second infusion pipe 212 is supplied to the pipe 250, respectively. Two fifth valves 262 are arranged on the two ends of the pipe 260, and are configured for whether the wet processing liquid in the first infusion pipe 211 and the second infusion pipe 212 is supplied to the pipe 260, respectively. Two sixth valves 272 are arranged on the two ends of the pipe 270, and are configured for whether the wet processing liquid in the first infusion pipe 211 and the second infusion pipe 212 is supplied to the pipe 270, respectively.

The sensor 281, the sensor 282, the sensor 283, the sensor 284, the sensor 285, the sensor 286 are electrically connected with the controlling device 290. To simplify the drawing, the electrical connecting relationship between the sensor 281, the sensor 282, the sensor 283, the sensor 284, the sensor 285, the sensor 286 and the controlling device 290 is not shown in FIG. 2. According to the sensed value sensed by the sensor 281, the controlling device 290 controls the valves 222 to open or close, thereby controlling whether the nozzle 221 sprays wet processing liquid on the substrate 10 or not. According to the sensed value sensed by the sensor 282, the controlling device 290 controls the valves 232 to open or close, thereby controlling whether the nozzles 231 spray wet processing liquid on the substrate 10 or not. According to the sensed value sensed by the sensor 283, the controlling device 290 controls the valves 242 to open or close, thereby controlling whether the nozzles 241 spray wet processing liquid on the substrate 10 or not. According to the sensed value sensed by the sensor 284, the controlling device 290 controls the valves 252 to open or close, thereby controlling whether the nozzle 251 sprays wet processing liquid on the substrate 10 or not. According to the sensed value sensed by the sensor 285, the controlling device 290 controls the valves 262 to open or close, thereby controlling whether the nozzles 261 spray wet processing liquid on the substrate 10 or not. According to the sensed value sensed by the sensor 286, the controlling device 290 controls the valve 272 to open or close, thereby controlling whether the nozzles 271 spray wet processing liquid on the substrate 10 or not.

In the present embodiment, the infusion device 210 includes first infusion pipe 211, and the second infusion pipe 213, and there are two valves on each spray pipe, the spray pressure of spraying the wet processing liquid is improved. Accordingly, the quality of the wet processing is improved.

While certain embodiments have been described and exemplified above, various other embodiments will be apparent to those skilled in the art from the foregoing disclosure. The disclosure is not limited to the particular embodiments described and exemplified but is capable of considerable variation and modification without departure from the scope and spirit of the appended claims.

What is claimed is:

1. An apparatus for wet processing a substrate, comprising:
a conveyor configured for conveying the substrate along a conveying direction, and
a plurality of parallel spray pipes, the spray pipes substantially parallel with the conveyor and substantially perpendicular to the conveying direction, each spray pipe consisting of at least one spray nozzle facing the conveyor, and the number of the at least one nozzle of each spray pipe increasing along the conveying direction.

2. The apparatus of claim 1, wherein the nozzles are arranged in a substantially isosceles triangular array, an inverted isosceles triangular array, or a substantially isosceles trapezoidal array along the conveying direction.

3. The apparatus of claim 1, wherein the spray pipes are equidistantly spaced.

4. The apparatus of claim 1, further comprising an infusion pipe communicating with the spray pipes, the infusion pipe being configured for supplying wet processing liquid to the spray pipes.

5. The apparatus of claim 4, wherein each of the spray pipes further comprises a valve located between the infusion pipe and the at least one nozzle thereof.

6. The apparatus of claim 5, further comprising a plurality of sensors spatially corresponding to the respective spray pipes, and a controlling device electrically connected with the sensors and the valves, each sensor being configured for sensing a position of the substrate relative to the corresponding spray pipe, and the controlling device being configured for controlling the corresponding valve to open or close based on the sensed value.

7. The apparatus of claim 6, wherein the substrate comprises a front edge, and a rear edge front edge, the front edge and the rear edge are perpendicular to the conveying direction, the controlling device is configured for storing a plurality of first predetermined values each associated with a distance between the front edge and a projection of a corresponding spray pipe on the substrate, and a plurality of second predetermined values each associated with a distance between the rear edge and a projection of the corresponding spray pipe on the substrate, the controlling device configured for controlling the valve of the corresponding spray pipe to open if the sensed value is equal to the first value, and controlling the valve of the corresponding spray pipe to close if the sensed value is equal to the second value.

8. The apparatus of claim 7, wherein each of the first predetermined values is equal to a distance between the front edge and a projection of a corresponding spray pipe on the substrate, and each of the second predetermined values is equal to a distance between the rear edge and a projection of the corresponding spray pipe on the substrate, the first values corresponding to the spray pipes and front edge gradually increasing along the conveying direction, the second values corresponding to the spray pipes and rear edge gradually increasing along the conveying direction.

9. The apparatus of claim 4, wherein the apparatus comprises two infusion pipes, the spray pipes are located between the infusion pipes, each of the spray pipes further comprises two valves arranged thereon, and the nozzles on the corresponding spray pipes are between the corresponding two valves on the corresponding spray pipes for controlling whether the at least one nozzle on each spray pipe sprays wet processing liquid on the substrate.

10. The apparatus of claim 1, wherein the nozzles are equidistantly spaced along a direction perpendicular to the conveying direction.

11. An apparatus for wet processing a substrate using wet processing liquid, comprising:
a conveyor configured for conveying the substrate along a conveying direction;
a plurality of spray pipes, each spray pipe consisting of at least one spray nozzle facing the conveyor, and the number of the at least one nozzle of each spray pipe increasing along the conveying direction;
an infusion pipe communicating with the spray pipes, the infusion pipe being configured for supplying wet processing liquid to the spray pipes, and
a plurality of valves arranged on the spray pipes respectively, each of the valves configured for controlling opening and closing of the corresponding at least one spray nozzle.

12. The apparatus of claim 11, wherein the nozzles are arranged in a substantially isosceles triangular array, an inverted isosceles triangular array, or a substantially isosceles trapezoidal array along the conveying direction.

13. The apparatus of claim 11, wherein the spray pipes are equidistantly spaced.

14. The apparatus of claim 11, wherein each of the spray pipes further comprises a valve located between the infusion pipe and the at least one nozzle thereof.

15. The apparatus of claim 14, further comprising a plurality of sensors spatially corresponding to the respective spray pipes, and a controlling device electrically connected with the sensors and the valves, each sensor being configured for sensing a position of the substrate relative to the corresponding spray pipe, and the controlling device being configured for controlling the corresponding valve to open or close based on the sensed value.

16. The apparatus of claim 15, wherein the substrate comprises a front edge, and a rear edge front edge, the front edge and the rear edge are perpendicular to the conveying direction, the controlling device is configured for storing a plurality of first predetermined values each associated with a distance between the front edge and a projection of a corresponding spray pipe on the substrate, and a plurality of second predetermined values each associated with a distance between the rear edge and a projection of the corresponding spray pipe on the substrate, the controlling device configured for controlling the valve of the corresponding spray pipe to open if the sensed value is equal to the first value, and controlling the valve of the corresponding spray pipe to close if the sensed value is equal to the second value.

17. The apparatus of claim 16, wherein each of the first predetermined values is equal to a distance between the front edge and a projection of a corresponding spray pipe on the substrate, and each of the second predetermined values is equal to a distance between the rear edge and a projection of the corresponding spray pipe on the substrate, the first values corresponding to the spray pipes and front edge gradually increasing along the conveying direction, the second values corresponding to the spray pipes and rear edge gradually increasing along the conveying direction.

18. The apparatus of claim 11, wherein the nozzles are equidistantly spaced along a direction perpendicular to the conveying direction.
